(19) United States
(12) Patent Application Publication
(10) Pub. No.: US 2026/0247650 A1
(43) Pub. Date: Aug. 20, 2026

(54) POWER SEMICONDUCTOR DEVICE

(71) Applicant: Device Dynamics Lab Co., Ltd., Zhubei City (TW)

(72) Inventors: Ming-Cheng LIN, Zhubei City (TW); Chao-Ta FAN, Zhubei City (TW); Chih-Kai CHANG, Zhubei City (TW)

(73) Assignee: Device Dynamics Lab Co., Ltd., Zhubei City (TW)

(21) Appl. No.: 19/538,617

(22) Filed: Feb. 12, 2026

(30) Foreign Application Priority Data
Feb. 14, 2025 (TW) 114105574

(51) Int. Cl. H10D 30/47; H10D 62/824; H10D 64/00; H10D 84/00

(52) U.S. Cl. CPC H10D 30/475; H10D 62/824; H10D 64/111; H10D 84/101

(57) ABSTRACT

A power semiconductor device includes a substrate layer, a semiconductor layer, a barrier layer, a source structure, a drain structure, first and second gate structures, and a field plate that cooperatively form an equivalent circuit including first and second transistors, and a Schottky diode. The barrier layer and the semiconductor layer cooperatively form a 2DEG. The first gate structure controls presence and movement of the 2DEG for controlling a current flow between the source structure and the drain structure. The second gate structure cooperates with the barrier layer to form a diode structure with Schottky diode characteristics. A drain terminal of the first transistor is electrically connected to a source terminal of the second transistor. A gate terminal of the second transistor is electrically connected to a cathode of the Schottky diode. An anode of the Schottky diode is electrically connected to a source terminal of the first transistor.

### CROSS-REFERENCE TO RELATED APPLICATION

This application claims priority to Taiwanese Invention Patent Application No. 114105574, filed on February 14, 2025, the entire disclosure of which is incorporated by reference herein.

### FIELD

The disclosure relates to a power semiconductor device.

### BACKGROUND

Third generation semiconductor (also known as the wide-bandgap semiconductor) materials include silicon carbide (SiC) and gallium nitride (GaN). The third generation semiconductor materials have favorable characteristics, such as relatively high carrier mobility and a relatively large bandgap. For example, a semiconductor device that is manufactured using GaN technology (also known as a GaN device) may have a figure of merit (FOM) that is 5 to 10 times higher than an FOM of a semiconductor device that is manufactured using silicon technology. As a result, the third generation semiconductor materials may be employed to manufacture devices for more advanced applications such as high-voltage power semiconductor devices and high-frequency communication devices.

FIGS. 1 and 2 are respectively a circuit diagram and a structural schematic diagram of a conventional power semiconductor device 11. The conventional power semiconductor device 11 includes a substrate layer 111, a GaN layer 112, and a barrier layer 113 that are stacked from bottom to top. The barrier layer 113 and the GaN layer 112 cooperatively form a two-dimensional electron gas (2DEG) between the barrier layer 113 and the GaN layer 112. The conventional power semiconductor device 11 further includes a source structure 114, a gate structure 115, and a drain structure 116 that are disposed on the barrier layer 113, and that are spaced apart from each other. The 2DEG forms an electron channel 117 that is shown as dashed lines in FIG. 2.

Since the conventional power semiconductor device 11 does not include any body diodes, conduction of a reverse current of the conventional power semiconductor device 11 occurs through the electron channel 117 for the conventional power semiconductor device 11, when, a source-to-drain voltage (Vsd) is equal to a gate-to-drain voltage (Vgd), and is greater than a threshold voltage (Vth); however, when the Vsd is equal to the Vgd, and is smaller than the Vth, the reverse current is blocked by the electron channel 117. This behavior of conduction and blocking of the reverse current may lead to relatively high power loss during reverse conduction of the conventional power semiconductor device 11.

In addition, the conventional power semiconductor device 11 may be affected by a dynamic Vth shift and a dynamic Vsd shift caused by gate charge trapping effects. These phenomena may reduce the operating current of the conventional power semiconductor device 11 and may result in additional reverse conduction losses.

### SUMMARY

Therefore, an object of the disclosure is to provide a power semiconductor device that can alleviate at least one of the drawbacks of the prior art.

According to an aspect of the disclosure, the power semiconductor device includes a substrate layer, a semiconductor layer disposed on the substrate layer, a barrier layer disposed on the semiconductor layer, a source structure formed on the barrier layer, a drain structure formed on the barrier layer, a first gate structure formed on the barrier layer between the source structure and the drain structure, a second gate structure formed on the barrier layer between the first gate structure and the drain structure, and a field plate disposed above the source structure, the first gate structure and the second gate structure. The barrier layer and the semiconductor layer cooperatively form a two-dimensional electron gas (2DEG) between the barrier layer and the semiconductor layer. The source structure and the drain structure are spaced apart from each other. The first gate structure is configured to control presence and movement of the 2DEG for controlling a current flow between the source structure and the drain structure. The second gate structure includes a second-gate conducting layer that is in contact with the barrier layer, and that is electrically connected to the source structure. The second-gate conducting layer and the barrier layer cooperatively form a diode structure with Schottky diode characteristics. The field plate is extended in a direction toward the drain structure. The second-gate conducting layer is electrically connected to the source structure via the field plate. The substrate layer, the semiconductor layer, the barrier layer, the source structure, the drain structure, the first gate structure and the second gate structure cooperatively form an equivalent circuit that includes a first transistor, a second transistor, and a Schottky diode. The first transistor has a source terminal, a gate terminal and a drain terminal. The second transistor has a source terminal, a gate terminal and a drain terminal. The Schottky diode has an anode and a cathode. The source structure and the drain structure respectively serve as the source terminal of the first transistor and the drain terminal of the second transistor. The first gate structure serves as the gate terminal of the first transistor. The diode structure serves as the Schottky diode. The second gate structure serves as the anode of the Schottky diode. For the equivalent circuit, the drain terminal of the first transistor is electrically connected to the source terminal of the second transistor. The gate terminal of the second transistor is electrically connected to the cathode of the Schottky diode. The anode of the Schottky diode is electrically connected to the source terminal of the first transistor.

According to another aspect of the disclosure, the power semiconductor device includes a first transistor, a second transistor and a Schottky diode. The first transistor has a source terminal, a gate terminal and a drain terminal. The second transistor has a source terminal, a gate terminal and a drain terminal. The Schottky diode has an anode and a cathode. The source terminal of the first transistor serves as a source terminal of the power semiconductor device. The drain terminal of the second transistor serves as a drain terminal of the power semiconductor device. The gate terminal of the first transistor serves as a gate terminal of the power semiconductor device. The drain terminal of the first transistor is electrically connected to the source terminal of the second transistor. The gate terminal of the second transistor is electrically connected to the cathode of the Schottky diode. The anode of the Schottky diode is electrically connected to the source terminal of the first transistor.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a circuit diagram of a conventional power semiconductor device.

FIG. 2 is a structural schematic diagram of the conventional power semiconductor device.

FIG. 3 is a circuit diagram of a power semiconductor device according to an embodiment of the present disclosure.

FIG. 4 is a structural schematic diagram of the power semiconductor device according to an embodiment of the present disclosure.

FIG. 5 is a perspective view illustrating the power semiconductor device according to an embodiment of the present disclosure.

FIG. 6 shows output characteristics respectively of the conventional power semiconductor device of FIG. 1, and the power semiconductor device according to an embodiment of the present disclosure.

FIG. 7 shows transfer characteristics respectively of the conventional power semiconductor device of FIG. 1, and the power semiconductor device according to an embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

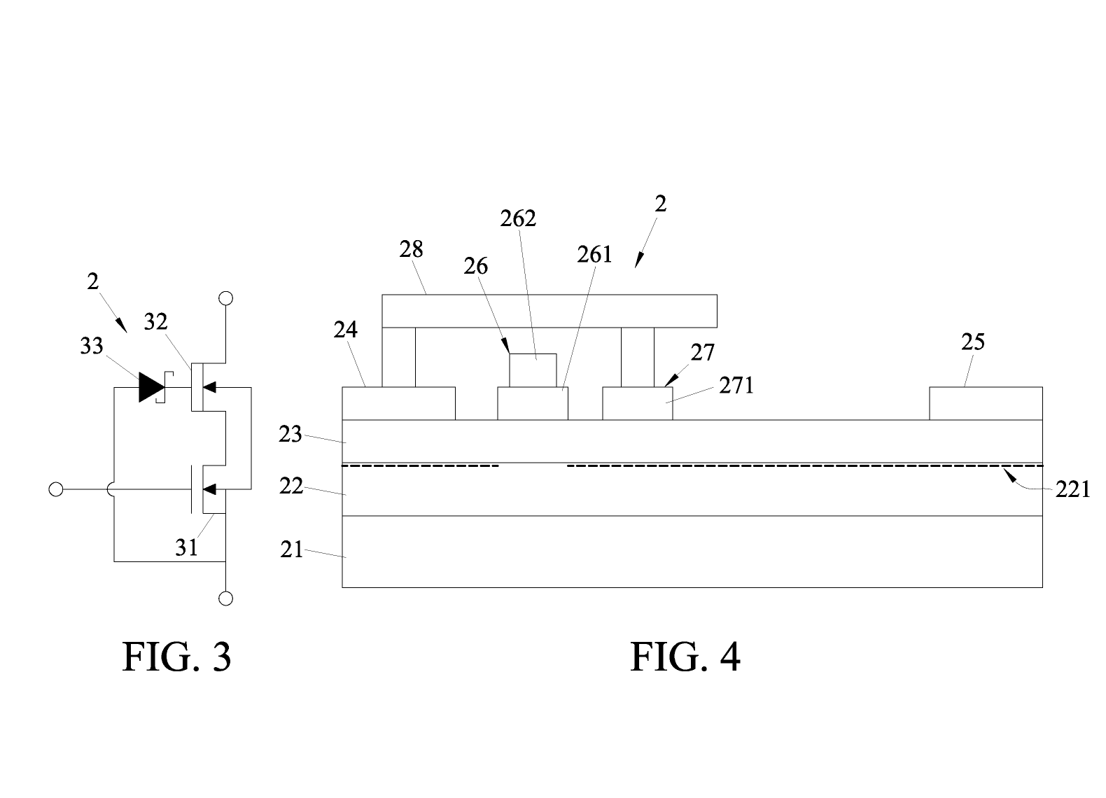

Referring to FIGS. 3 and 4, a power semiconductor device 2 according to an embodiment of the present disclosure includes a substrate layer 21, a semiconductor layer 22, a barrier layer 23, a source structure 24, a drain structure 25, a first gate structure 26, and a second gate structure 27.

The substrate layer 21 includes sapphire (Al₂O₃), silicon carbide (SiC) or silicon (Si).

The semiconductor layer 22 includes gallium nitride (GaN) (hereinafter referred to as “the GaN layer 22”), and is disposed on the substrate layer 21.

The barrier layer 23 is disposed on the GaN layer 22. The barrier layer 23 and the GaN layer 22 cooperatively form a two-dimensional electron gas (2DEG) between the barrier layer 23 and the GaN layer 22. Specifically, electrons with high density and high mobility are induced into a heterostructure interface between the barrier layer 23 and the GaN layer 22, and the electrons form the 2DEG, which serves as an electron channel 221. The barrier layer 23 includes aluminum gallium nitride (AlGaN). For example, the barrier layer 23 includes Al_{X}Ga_{1-X}N, where 0 < X < 1. The electron channel 221 is shown as dashed lines in FIG. 4.

The source structure 24 and the drain structure 25 are formed on the barrier layer 23. The source structure 24 and the drain structure 25 are spaced apart from each other. In one embodiment, the source structure 24 and the drain structure 25 each include a nickel-gold (Ni/Au) stack, a titanium-aluminum (Ti/Al) stack, or a titanium nitride (TiN) layer. The source structure 24 and the barrier layer 23 cooperatively form an ohmic contact between the source structure 24 and the barrier layer 23, and the drain structure 25 and the barrier layer 23 cooperatively form another ohmic contact between the drain structure 25 and the barrier layer 23.

The first gate structure 26 is formed on the barrier layer 23 between the source structure 24 and the drain structure 25, and is configured to control presence and movement of the 2DEG for controlling a current flow between the source structure 24 and the drain structure 25. Specifically, when the 2DEG is present and electrons therein are able to move through the electron channel 221, current is able to flow between the source structure 24 and the drain structure 25. When the 2DEG is absent, current is not able to flow between the source structure 24 and the drain structure 25. The first gate structure 26 includes a p-type-semiconductor layer 261 formed on the barrier layer 23, and a first-gate conducting layer 262 disposed on the p-type-semiconductor layer 261. In one embodiment, the p-type-semiconductor layer 261 includes GaN, but the p-type-semiconductor layer 261 is not limited to such. In one embodiment, the first-gate conducting layer 262 includes a metal, but the disclosure is not limited to such.

The second gate structure 27 is formed on the barrier layer 23 between the first gate structure 26 and the drain structure 25. The second gate structure 27 includes a second-gate conducting layer 271 that is in contact with the barrier layer 23, and that is electrically connected to the source structure 24. The second-gate conducting layer 271 and the barrier layer 23 cooperatively form a diode structure with Schottky diode characteristics. That is to say, the second-gate conducting layer 271 and the barrier layer 23 cooperatively form a Schottky contact between the second-gate conducting layer 271 and the barrier layer 23. In one embodiment, the second-gate conducting layer 271 includes a metal, but the second-gate conducting layer 271 is not limited to such.

It should be noted that, disposing the second gate structure 27 in between the first gate structure 26 and the drain structure 25 may reduce a voltage difference taken at the first gate structure 26. Specifically, when the second gate structure 27 is not provided, the voltage difference that is taken at the first gate structure 26 is the voltage difference between the drain structure 25 and the first gate structure 26, which may result in relatively greater gate charge trapping effects. When the second gate structure 27 is provided, the voltage difference taken at the first gate structure 26 is a voltage difference between the second gate structure 27 and the first gate structure 26, and the voltage difference between the second gate structure 27 and the first gate structure 26 is significantly smaller than the voltage difference between the drain structure 25 and the first gate structure 26, thereby reducing the gate charge trapping effects. Besides that, the second-gate conducting layer 271 of the second gate structure 27 may include metal or a metal compound, which provides the second-gate conducting layer 271 with characteristics such as high conductivity that may significantly reduce the gate charge trapping effects. Therefore, a voltage difference between the drain structure 25 and the second gate structure 27 may not affect an operation of the second gate structure 27.

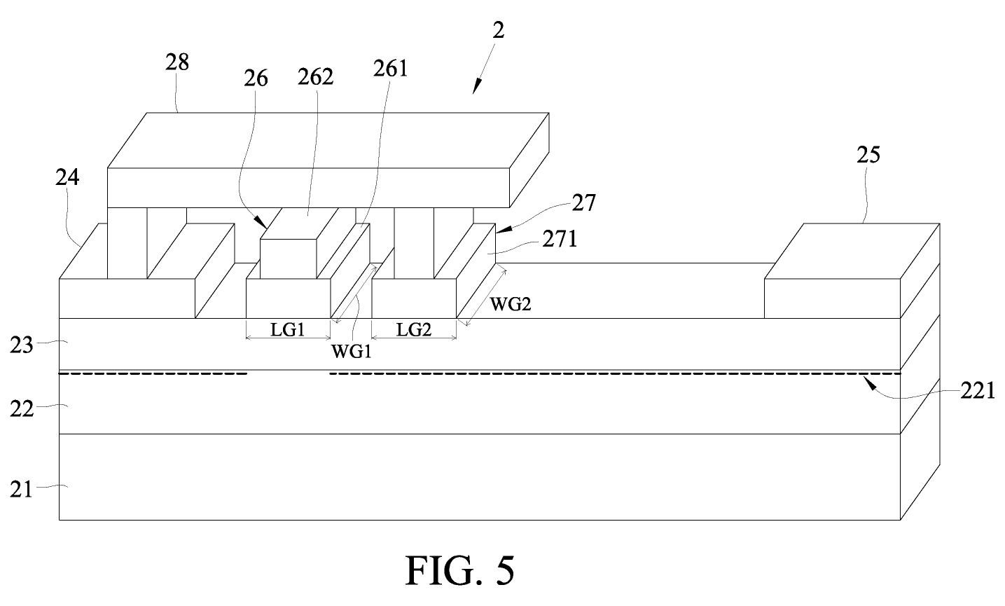

Referring to FIG. 5, in one embodiment, a length and a width of the first gate structure 26 (LG1, WG1), and a length and a width of the second gate structure 27 (LG2, WG2) are adjustable. Adjustments to the dimensions of the first gate structure 26 (i.e., LG1 and WG1) and dimensions of the second gate structure 27 (i.e., LG2 and WG2) need only fulfil the requirements of, meeting voltage resistance and current handling capabilities of the power semiconductor device 2, and should ensure that the width of the first gate structure 26 (WG1) is not smaller than the width of the second gate structure 27 (WG2). It should be noted that, the second gate structure 27 generates capacitance, and the capacitance formed can be reduced by reducing the width of the second gate structure 27 (WG2). For example, the width of the second gate structure 27 (WG2) can be designed to be smaller than the width of the first gate structure 26 (WG1). In another example, the second gate structure 27 can be segmented into a plurality of finger-like segments, extending in parallel and spaced apart from each other at a predetermined ratio (e.g., forming a comb shape), such that a combined width of the finger-like segments is substantially the same as the width of the first gate structure 26 (WG1). By virtue of these arrangements, the second gate structure 27 may continue to provide the beneficial effects as mentioned above to the power semiconductor device 2, while at the same time reduce the capacitance generated by the second gate structure 27.

The power semiconductor device 2 further includes a field plate 28 that is disposed above the source structure 24, the first gate structure 26, and the second gate structure 27, and that is extended in a direction toward the drain structure 25. In one embodiment, the field plate 28 includes aluminum (Al) or copper (Cu), but the field plate 28 is not limited to such. The second-gate conducting layer 271 is electrically connected to the source structure 24 via the field plate 28.

In one embodiment, the substrate layer 21, the GaN layer 22, the barrier layer 23, the source structure 24, the drain structure 25, the first gate structure 26, the second gate structure 27, and the field plate 28 cooperatively form an equivalent circuit as shown in FIG. 3 that includes a first transistor 31 having a source terminal, a gate terminal and a drain terminal, a second transistor 32 having a source terminal, a gate terminal and a drain terminal, and a Schottky diode 33 having an anode and a cathode.

In one embodiment, the first transistor 31 is exemplified as an enhancement-mode (E-mode) GaN high electron mobility transistor (HEMT), and the second transistor 32 is exemplified as a depletion-mode (D-mode) GaN HEMT. The first transistor 31 and the second transistor 32 each have dimensions that comply with the requirements of a power device.

The source structure 24 and the drain structure 25 respectively serve as the source terminal of the first transistor 31 and the drain terminal of the second transistor 32. The first gate structure 26 serves as the gate terminal of the first transistor 31. The diode structure serves as the Schottky diode 33. In one embodiment, the Schottky diode 33 serves as a body Schottky diode, which provides functions of a body diode. The second gate structure 27 serves as the anode of the Schottky diode 33.

For the equivalent circuit, the source terminal of the first transistor 31 serves as a source terminal of the power semiconductor device 2. The drain terminal of the second transistor 32 serves as a drain terminal of the power semiconductor device 2. The gate terminal of the first transistor 31 serves as a gate terminal of the power semiconductor device 2. The drain terminal of the first transistor 31 is electrically connected to the source terminal of the second transistor 32. The gate terminal of the second transistor 32 is electrically connected to the cathode of the Schottky diode 33, and the anode of the Schottky diode 33 is electrically connected to the source terminal of the first transistor 31.

In one embodiment, a threshold voltage (Vth) of the first transistor 31 is about 1.5 V, and a Vth shift of the first transistor 31 is about 1 V. Specifically, the Vth shift is a difference between the Vth in an ideal situation, and the Vth during an operating situation (i.e., when in operation). A Vth of the second transistor 32 is about -2 V. A forward voltage of the Schottky diode 33 is about 0.8 V.

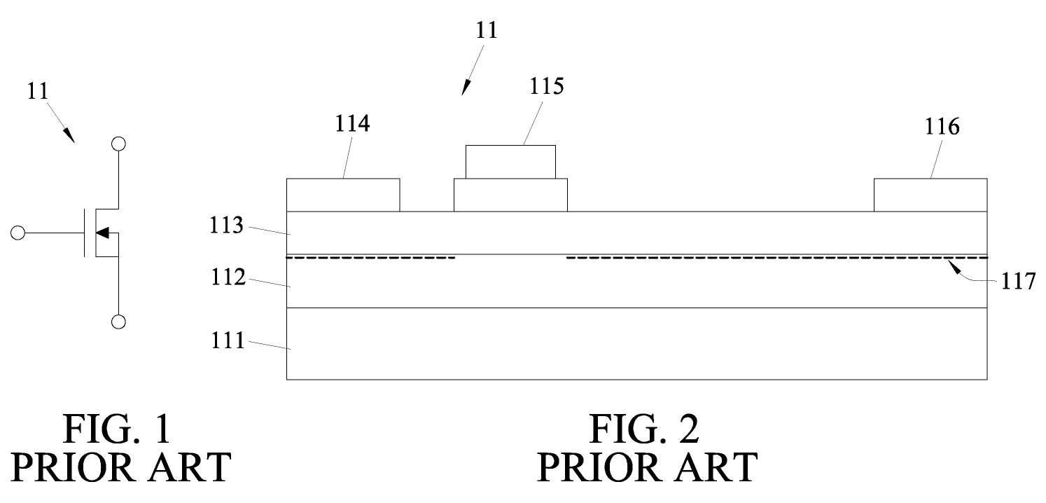

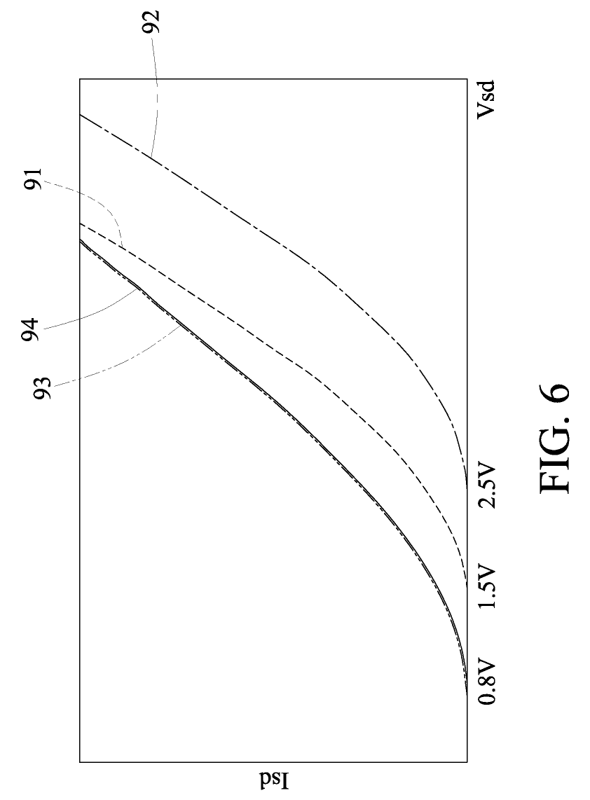

Referring to FIGS. 2, 4 and 6, output characteristics respectively of the conventional power semiconductor device 11 of FIGS. 1 and 2, and the power semiconductor device 2 of this disclosure are presented in FIG. 6. The output characteristics are presented in a line graph having a y-axis that is denoted by the source-to-drain current (Isd) and an x-axis that is denoted by the source-to-drain voltage (Vsd). In the line graph, plot 91 and plot 92 respectively denote the output characteristics of the conventional power semiconductor device 11 in the ideal situation and in the operating situation, plot 93 and plot 94 respectively denote the output characteristics of the power semiconductor device 2 in the ideal situation and in the operating situation. It can be seen from the plot 91 and the plot 92 that a Vsd shift of the conventional power semiconductor device 11 is about 1 V. Specifically, the Vsd shift is a difference between the Vsd in the ideal situation and the Vsd during the operating situation. From the plot 93 and the plot 94, it can be seen that there is almost no Vsd shift for the power semiconductor device 2 of this disclosure.

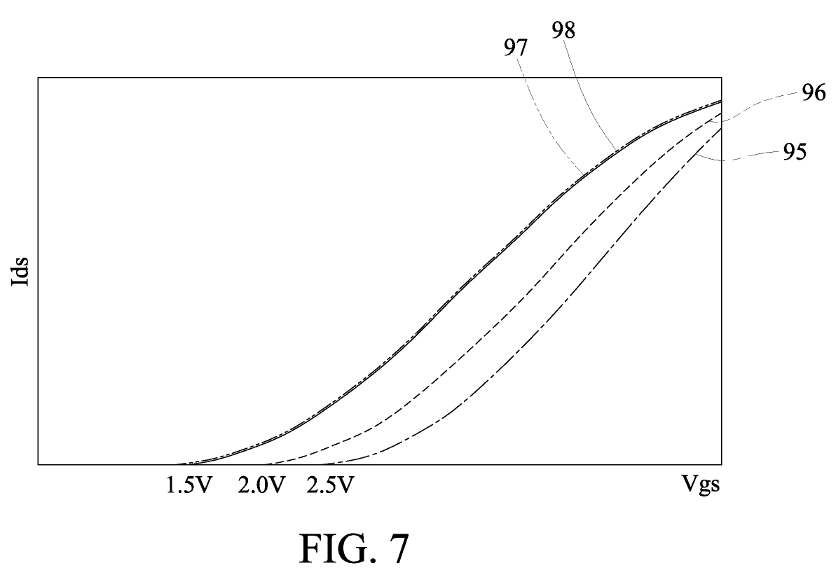

Referring to FIGS. 2, 4 and 7, transfer characteristics respectively of the conventional power semiconductor device 11, and the power semiconductor device 2 of this disclosure are presented in FIG. 7. The transfer characteristics are presented in a line graph having a y-axis that is denoted by the drain-to-source current (Ids) and an x-axis that is denoted by the gate-to-source voltage (Vgs). In the line graph, plot 97 and plot 95 respectively denote the transfer characteristics of the conventional power semiconductor device 11 in the ideal situation and in the operating situation, and plot 98 and plot 96 respectively denote the transfer characteristics of the power semiconductor device 2 in the ideal situation and in the operating situation. It can be seen from FIG. 7 that, a difference in voltage between the plot 97 and the plot 95 (which is about 1 V) is greater than a difference in voltage between the plot 98 and the plot 96 (which is about 0.5 V). That is to say, the Vth shift of the conventional power semiconductor device 11 is greater than the Vth shift of the power semiconductor device 2 of this disclosure.

In summary, by virtue of having the second gate structure 27 disposed in between the first gate structure 26 and the drain structure 25, the voltage difference taken at the first gate structure 26 may be reduced, thereby reducing the influence caused by the gate charge trapping effects. In addition, by virtue of the second-gate conducting layer 271 cooperating with the barrier layer 23 to form the diode structure that has the characteristics of a Schottky diode, a body Schottky diode may be formed, and the body Schottky diode may be integrated into the power semiconductor device 2 to provide functions of a body diode. Therefore, the power semiconductor device 2 of this disclosure is able to reduce a dynamic Vth shift and a dynamic Vsd shift of the power semiconductor device 2, and also able to reduce power loss during reverse conduction.

Furthermore, by virtue of having the field plate 28, an electric field distribution of the power semiconductor device 2 can be improved, and a performance of the power semiconductor device 2 can be enhanced.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A power semiconductor device, comprising:
a substrate layer;
a semiconductor layer disposed on said substrate layer;
a barrier layer disposed on said semiconductor layer, said barrier layer and said semiconductor layer cooperatively forming a two-dimensional electron gas (2DEG) between said barrier layer and said semiconductor layer;
a source structure formed on said barrier layer;
a drain structure formed on said barrier layer, said source structure and said drain structure being spaced apart from each other;
a first gate structure formed on said barrier layer between said source structure and said drain structure, and configured to control presence and movement of the 2DEG for controlling a current flow between said source structure and said drain structure;
a second gate structure formed on said barrier layer between said first gate structure and said drain structure, including a second-gate conducting layer that is in contact with said barrier layer and that is electrically connected to said source structure, said second-gate conducting layer and said barrier layer cooperatively forming a diode structure with Schottky diode characteristics; and
a field plate disposed above said source structure, said first gate structure and said second gate structure, and extended in a direction toward said drain structure, said second-gate conducting layer being electrically connected to said source structure via said field plate;
wherein said substrate layer, said semiconductor layer, said barrier layer, said source structure, said drain structure, said first gate structure and said second gate structure cooperatively form an equivalent circuit that includes a first transistor having a source terminal, a gate terminal and a drain terminal, a second transistor having a source terminal, a gate terminal and a drain terminal, and a Schottky diode having an anode and a cathode;
wherein said source structure and said drain structure respectively serve as said source terminal of said first transistor and said drain terminal of said second transistor, said first gate structure serves as said gate terminal of said first transistor, said diode structure serves as said Schottky diode, and said second gate structure serves as said anode of said Schottky diode; and
wherein for the equivalent circuit, said drain terminal of said first transistor is electrically connected to said source terminal of said second transistor, said gate terminal of said second transistor is electrically connected to said cathode of said Schottky diode, and said anode of said Schottky diode is electrically connected to said source terminal of said first transistor.

2. The power semiconductor device as claimed in claim 1, wherein said first gate structure includes a p-type-semiconductor layer formed on said barrier layer, and a first-gate conducting layer disposed on said p-type-semiconductor layer.

3. The power semiconductor device as claimed in claim 2, wherein said p-type-semiconductor layer includes gallium nitride (GaN).

4. The power semiconductor device as claimed in claim 1, wherein said barrier layer includes Al_{X}Ga_{1-X}N, where 0 < X < 1.

5. The power semiconductor device as claimed in claim 1, wherein said source structure and said barrier layer cooperatively form an ohmic contact between said source structure and said barrier layer, and said drain structure and said barrier layer cooperatively form another ohmic contact between said drain structure and said barrier.

6. The power semiconductor device as claimed in claim 1, wherein said substrate layer includes one of sapphire, silicon carbide, and silicon.

7. The power semiconductor device as claimed in claim 1, wherein said semiconductor layer includes gallium nitride (GaN).

8. The power semiconductor device as claimed in claim 1, wherein said second-gate conducting layer includes a metal.

9. A power semiconductor device, comprising:
a first transistor having a source terminal, a gate terminal and a drain terminal;
a second transistor having a source terminal, a gate terminal and a drain terminal; and
a Schottky diode having an anode and a cathode;
wherein said source terminal of said first transistor serves as a source terminal of said power semiconductor device, said drain terminal of said second transistor serves as a drain terminal of said power semiconductor device, and said gate terminal of said first transistor serves as a gate terminal of said power semiconductor device;
wherein said drain terminal of said first transistor is electrically connected to said source terminal of said second transistor, said gate terminal of said second transistor is electrically connected to said cathode of said Schottky diode, and said anode of said Schottky diode is electrically connected to said source terminal of said first transistor.
